(19) United States
(12) Patent Application Publication
(10) Pub. No.: US 2012/0235220 A1
(43) Pub. Date: Sep. 20, 2012

(54) SEMICONDUCTOR DEVICE

(75) Inventors: Katsuyuki SEKINE, Mie-ken (JP); Masaaki HIGUCHI, Mie-ken (JP)

(73) Assignee: Kabushiki Kaisha Toshiba, Tokyo (JP)

(21) Appl. No.: 13/234,406

(22) Filed: Sep. 16, 2011

(30) Foreign Application Priority Data
Mar. 15, 2011 (JP) 2011-056437

(51) Int. Cl. H01L 29/792

(52) U.S. Cl. 257/324; 257/E29.309

(57) ABSTRACT

According to one embodiment, a semiconductor device includes a substrate, a stacked body, a first insulating film, a charge storage film, a second insulating film and a channel body. The stacked body includes a plurality of electrode layers and insulating layers which are alternately stacked above the substrate. The first insulating film is provided on a side wall of a hole which is formed through the stacked body. The charge storage film is provided on an inner side of the first insulating film. The charge storage film includes a protrusion part which protrudes toward the electrode layer with facing the electrode layer and has a film thickness thicker than a film thickness of a part other than the protrusion part. The second insulating film is provided on an inner side of the charge storage film. The channel body is provided on an inner side of the second insulating film.

### CROSS-REFERENCE TO RELATED APPLICATION

This application is based upon and claims the benefit of priority from Japanese Patent Application No. 2011-056437, filed on Mar. 15, 2011; the entire contents of which are incorporated herein by reference.

### FIELD

Embodiments described herein relate generally to a semiconductor device.

### BACKGROUND

There is proposed a memory device in which memory cells are arranged in a three-dimensional way by forming a memory hole in a stacked body obtained by alternately stacking a plurality of electrode layers that function as control gates of memory cells and a plurality of insulating layers, forming a memory film including a charge storage film on a side wall of the memory hole and then, providing silicon serving as a channel in the memory hole.

Furthermore, in such a memory device, there is also proposed a structure for suppressing the diffusion of a charge stored in the charge storage film, in the cell stacking direction within the film. However, the structure can affect other characteristics.

### BRIEF DESCRIPTION OF THE DRAWINGS

FIG. 1 is a schematic perspective view of a semiconductor device of an embodiment;

FIGS. 2A and 2B are enlarged schematic cross-sectional views of a relevant part of the semiconductor device of the embodiment;

FIGS. 3A to 6B are schematic cross-sectional views showing a method for manufacturing the semiconductor device of the embodiment; and

FIG. 7 is a schematic perspective view showing another specific example of a memory string in the semiconductor device of the embodiment.

### DETAILED DESCRIPTION

According to one embodiment, a semiconductor device includes a substrate, a stacked body, a first insulating film, a charge storage film, a second insulating film and a channel body. The stacked body includes a plurality of electrode layers and a plurality of insulating layers which are alternately stacked above the substrate. The first insulating film is provided on a side wall of a hole which is formed through the stacked body. The charge storage film is provided on an inner side of the first insulating film. The second insulating film is provided on an inner side of the charge storage film. The channel body is provided on an inner side of the second insulating film. The charge storage film includes a protrusion part which protrudes toward the electrode layer with facing the electrode layer and has a film thickness thicker than a film thickness of a part other than the protrusion part.

Various embodiments will be described hereinafter with reference to the accompanying drawings. In the drawings shown below, like components are marked with like reference numerals.

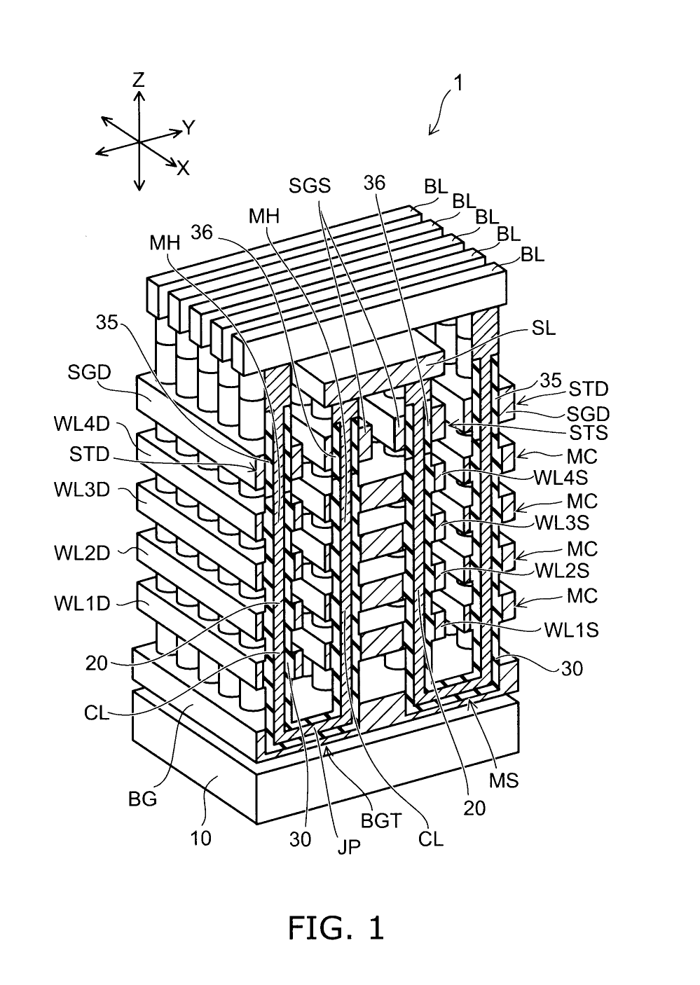

FIG. 1 is a schematic perspective view of a memory cell array of a semiconductor device 1 of the embodiment. In FIG. 1, for convenience of clarification, an insulating part other than an insulating film formed on an inner wall of a memory hole MH is not shown.

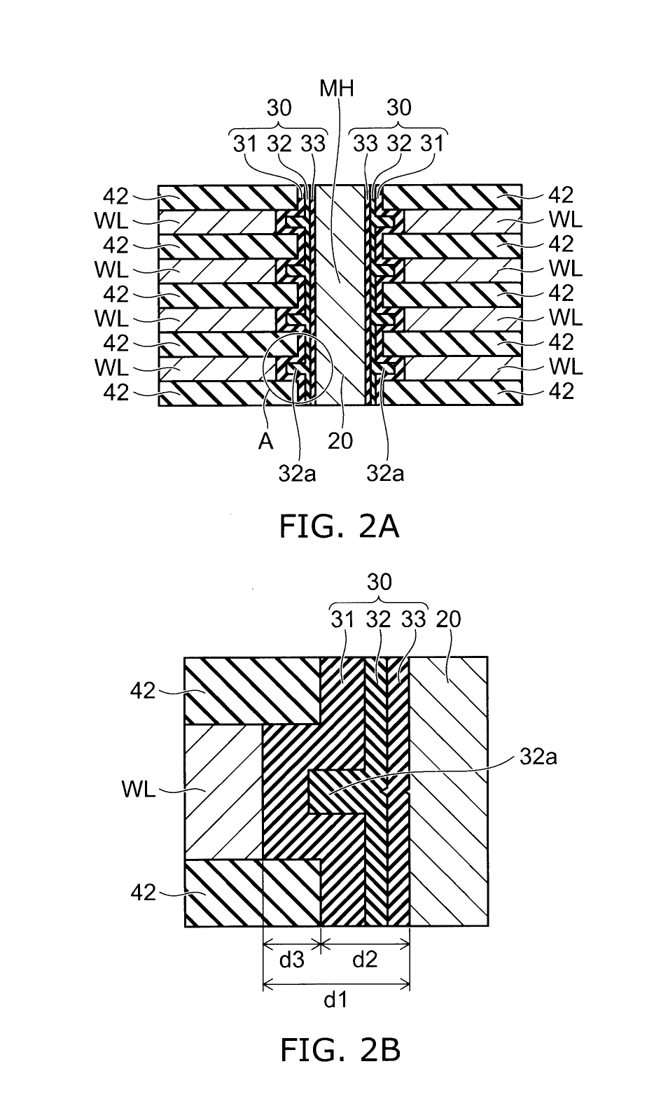

FIG. 2A is an enlarged cross-sectional view of a region where memory cells are provided in FIG. 1 and FIG. 2B is an enlarged view of a section A in FIG. 2A.

In FIG. 1, for convenience of explanation, an XYZ perpendicular coordinate system is introduced. In this coordinate system, two directions that are parallel to a major surface of a substrate 10 and are perpendicular to each other are defined as an X direction and a Y direction and a direction perpendicular to both of the X direction and the Y direction is defined as a Z direction.

In FIG. 1, a back gate BG is provided on the substrate 10 through an insulating layer not shown. The back gate BG is an impurity-doped and electrically conductive silicon layer.

A plurality of electrode layers WL1D, WL2D, WL3D, WL4D, WL1S, WL2S, WL3S, and WL4S and a plurality of insulating layers 42 (shown in FIG. 2A) are alternately stacked on the back gate BG.

The electrode layer WL1D and the electrode layer WL1S are provided in the same layer representing the first electrode layer from the bottom. The electrode layer WL2D and the electrode layer WL2S are provided in the same layer representing the second electrode layer from the bottom. The electrode layer WL3D and the electrode layer WL3S are provided in the same layer representing the third electrode layer from the bottom. The electrode layer WL4D and the electrode layer WL4S are provided in the same layer representing the fourth electrode layer from the bottom.

The electrode layer WL1D is separated from the electrode layer WL1S in the Y direction. The electrode layer WL2D is separated from the electrode layer WL2S in the Y direction. The electrode layer WL3D is separated from the electrode layer WL3S in the Y direction. The electrode layer WL4D is separated from the electrode layer WL4S in the Y direction.

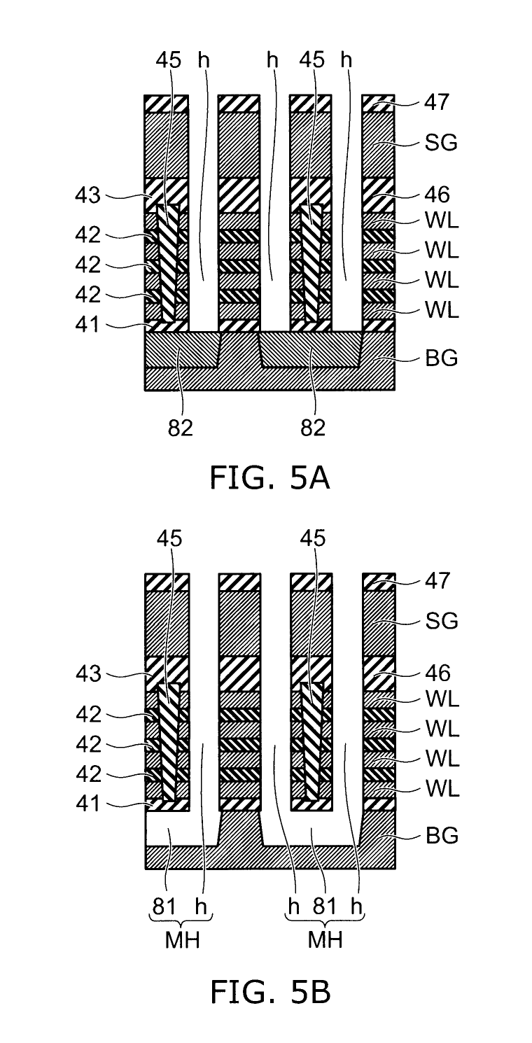

An insulator 45 shown in FIGS. 5A and 5B is provided between the electrode layer WL1D and the electrode layer WL1S, between the electrode layer WL2D and the electrode layer WL2S, between the electrode layer WL3D and the electrode layer WL3S, and between the electrode layer WL4D and the electrode layer WL4S.

The electrode layers WL1D, WL2D, WL3D, and WL4D are provided between the back gate BG and the drain-side selection gate SGD. The electrode layers WL1S, WL2S, WL3S, and WL4S are provided between the back gate BG and a source-side selection gate SGS.

The number of electrode layers WL1D, WL2D, WL3D, WL4D, WL1S, WL2S, WL3S, and WL4S is optional and is not limited to four shown in FIG. 1. In following description, each of the electrode layer WL1D, WL2D, WL3D, WL4D, WL1S, WL2S, WL3S, and WL4S may be sometimes referred to as merely electrode layer WL.

The electrode layer WL is an impurity-doped and electrically conductive polycrystalline silicon layer or a metal layer. In the case of polycrystalline silicon electrode layer WL, n-type is more preferable than p-type in terms of erasure characteristic. In the case of metal electrode layer WL, higher work function is more preferable in terms of erasure characteristic.

The insulating layer 42 is a silicon oxide layer or a silicon nitride layer. Alternatively, the insulating layer 42 is not limited to the silicon oxide layer or the silicon nitride layer and may be a stacked structure formed of the silicon oxide layer and the silicon nitride layer.

The drain-side selection gate SGD is provided on the electrode layer WL4D through an insulating layer not shown. The drain-side selection gate SGD is, for example, an impurity-doped and electrically conductive silicon layer.

The source-side selection gate SGS is provided on the electrode layer WL4S through an insulating layer not shown. The source-side selection gate SGS is, for example, an impurity-doped and electrically conductive silicon layer.

The drain-side selection gate SGD is separated from the source-side selection gate SGS in the Y direction. In following description, the drain-side selection gate SGD and the source-side selection gate SGS may be collectively referred to merely selection gate SG without being distinguished from each other.

A source layer SL is provided on the source-side selection gate SGS through an insulating layer not shown. The source layer SL is a metal layer or an impurity-doped and electrically conductive silicon layer.

A plurality of bit lines BL are provided on the drain-side selection gate SGD and the source layer SL through an insulating layer not shown. Each of the bit lines BL extends in the Y direction.

A plurality of U-like memory holes MH are formed at the back gate BG and a stacked body on the back gate BG. A hole is formed through the electrode layers WL1D to WL4D and drain-side selection gate SGD and extends in the Z direction. A hole is formed through the electrode layers WL1S to WL4S and the source-side selection gate SGS and extends in the Z direction. The pair of holes extending in the Z direction are connected to each other via a depression part formed in the back gate BG and constitute the U-like memory holes MH.

A U-like channel body 20 is provided within the memory hole MH. The channel body 20 is made of amorphous silicon, polycrystalline silicon or monocrystalline silicon.

A memory film 30 described later is provided between the channel body 20 and the inner wall of the memory hole MH.

A gate insulating film 35 is provided between the channel body 20 and the drain-side selection gate SGD. A gate insulating film 36 is provided between the channel body 20 and the source-side selection gate SGS.

The structure is not limited to a structure in which all inside the memory hole MH are filled with the channel body 20, and the channel body 20 may be formed so that a cavity is left on the side of a central axis of the memory hole MH and an insulator may be buried in the inner cavity.

The drain-side selection gate SGD, the channel body 20 and the gate insulating film 35 between the channel body 20 and the drain-side selection gate SGD constitute a drain-side selection transistor STD. The channel body 20 above the drain-side selection transistor STD is connected to the bit lines BL.

The source-side selection gate SGS, the channel body 20 and the gate insulating film 36 between the channel body 20 and the source-side selection gate SGS constitute a source-side selection transistor STS. The channel body 20 above the source-side selection transistor STS is connected to the source layer SL.

The back gate BG, and the channel body 20 and the memory film 30 which are provided in the back gate BG constitute a back gate transistor BGT.

A plurality of memory cells MC using the electrode layers WL4D to WL1D as control gates are provided between the drain-side selection transistor STD and the back gate transistor BGT. Similarly, a plurality of memory cells MC using the electrode layers WL1S to WL4S are provided between the back gate transistor BGT and the source-side selection transistor STS.

The plurality of memory cells MC, the drain-side selection transistor STS, the back gate transistor BGT and the source-side selection transistor STS are serially connected through to one another the channel body 20 to constitute a U-like memory string MS.

One memory string MS has a pair of columnar parts CL extending a stacking direction of the stacked body including the plurality of electrode layers WL and a joint part JP that is buried in the back gate BG and joints the pair of columnar parts CL to each other. The plurality of memory strings MS are arranged in the X direction and the Y direction, and thus the plurality of memory cells are provided in the X direction, the Y direction and the Z direction in a three-dimensional way.

Next, with reference to FIGS. 2A and 2B, the memory film 30 will be described.

A block film 31 as a first insulating film, a charge storage film 32 and a tunnel film 33 as a second insulating film are provided between each of the electrode layers WL and the channel body 20 in this order from the side of the electrode layer WL. The block film 31 is in contact with the electrode layer WL, the tunnel film 33 is in contact with the channel body 20 and the charge storage film 32 is provided between the block film 31 and the tunnel film 33.

The channel body 20 functions as a channel of the transistor constituting the memory cell, the electrode layer WL functions as the control gate of the transistor and the charge storage film 32 functions as a data storage layer for storing a charge injected from the channel body 20. That is, the memory cell having a structure in which the channel is surrounded by the control gate is formed at an intersecting part of the channel body 20 and each electrode layer WL.

The semiconductor device 1 of the embodiment is a nonvolatile semiconductor storage device that can electrically erase and write data freely and hold stored contents even if power is turned off.

The memory cell is, for example, a charge trap-type memory cell. The charge storage film 32 has a lot of trap sites for capturing the charge and is formed of a silicon nitride film, for example. Alternatively, a high dielectric insulating film containing hafnia, zirconia or the like is used as the charge storage film 32.

The silicon nitride film has a relatively low charge movement speed in the film and is excellent in the charge holding property. The high dielectric insulating film containing hafnia, zirconia or the like can have a wide memory window.

When a charge is injected from the channel body 20 into the charge storage film 32 or a charge stored in the charge storage film 32 is diffused into the channel body 20, the tunnel film 33 becomes a potential barrier. The tunnel film 33 is, for example, a silicon oxide film or a silicon oxynitride film. Alternatively, the tunnel film 33 is not limited to such monolayer and may be a stacked film of a silicon oxide film and a silicon oxynitride film. The silicon oxynitride film has an excellent resistance against writing and erasing stresses.

The block film 31 blocks the charge stored in the charge storage film 32 from being diffused into the electrode layer WL. The block film 31 is, for example, a silicon oxide film. A stacked film of a silicon nitride film and a high dielectric insulating film may be used as the block film 31. Alternately, a high dielectric insulating film that contains alumina or the like and has a high barrier to electrons may be used as the block film 31.

The insulating layer 42 protrudes toward the channel body 20 further than the electrode layer WL protrudes. Conversely speaking, the electrode layer WL is distant from the channel body 20 further than the insulating layer 42 is distant. Accordingly, a step is formed between the insulating layer 42 and the electrode layer WL. The block film 31 is formed along the step.

The charge storage film 32 has a protrusion part 32a provided so as to protrude toward the electrode layer WL at a part opposite to the electrode layer WL. A depression part is formed at a position facing the electrode layer WL on the block film 31 formed along the step between the insulating layer 42 and the electrode layer WL. A part of the charge storage film 32 is buried in the depression part to form the protrusion part 32a.

The film thickness of the protrusion part 32a (film thickness in the protruding direction toward the electrode layer WL) is larger than the film thickness of the other part of the charge storage film 32. An end part on the side of the electrode layer WL and side walls on the side of the insulating layer 42 in the protrusion part 32a are covered with the block film 31 in contact with each other.

The thickness of the block film 31 between the electrode layer WL and the protrusion part 32a is thinner than the thickness of the block film 31 between the electrode layer WL and the charge storage film 32. That is, the thickness of the block film 31 between the electrode layer WL and the charge storage film 32 is relatively thin in the center in the thickness direction of the electrode layer WL (the center of the memory cell) and is relatively thick in the vicinity of the edge of the electrode layer WL.

Accordingly, tunnel electric field becomes high in the center of the memory cell and thus, writing of data to the charge storage film 32 (electron injection) easily occurs. Most of injected electrons are stored in the vicinity of an interface between the protrusion part 32a and the block film 31 at a front end of the protrusion part 32a.

In the charge holding state, electrons attempt to move from the front end of the protrusion part 32a to the tunnel film 33 by self-electric field. However, in the embodiment, since the block film 31 exists on the side walls of the protrusion part 32a, the electrons stored in the protrusion part 32a are prevented from moving to the other adjacent memory cell. As a result, the memory cell having an excellent charge holding property can be realized.

The memory film 30 has unevenness on the side of the electrode layer WL and the insulating layer 42, and is substantially flat on the side of the channel body 20. An interface between the tunnel film 33 and the channel body 20 extends approximately flatly in the extending direction of the memory hole MH. The electrode layer WL is retracted from the interface between the channel body 20 and the tunnel film 33, which extends approximately flatly, so as to be away from the channel body 20 further than the insulating layer 42 is away. Accordingly, a distance d1 between the electrode layer WL and the channel body 20 is longer than a distance d2 between the insulating layer 42 and the channel body 20.

There is a case where a depression part recessed in the protruding direction of the protrusion part 32a is formed on the protrusion part 32a on the side of the interface between the charge storage film 32 and the tunnel film 33. Then, there is a case where a protrusion part protruding toward the charge storage film 32 is formed on the tunnel film 33 so as to conform to the above-mentioned depression part, and further, a protrusion part protruding toward the tunnel film 33 is formed on the channel body 20. Even in such cases, by appropriately adjusting the film thickness of the electrode layer WL, the amount of retraction of the electrode layer WL relative to the insulating layer 42, and film thickness of each of the block film 31, the charge storage film 32 and the tunnel film 33, a film thickness difference between a part facing the protrusion part 32a of the charge storage film 32 and a part not facing the protrusion part 32a in the tunnel film 33 is smaller than a film thickness difference between the protrusion part 32a and the other part in the charge storage film 32. Further, a film thickness difference between a part facing the protrusion part 32a of the charge storage film 32 and a part not facing the protrusion part 32a in the channel body 20 is smaller than a film thickness difference between the part facing the protrusion part 32a and a part not facing the protrusion part 32a in the tunnel film 33. That is, the amount of local protrusion toward the electrode layer WL is decreased in the order of the channel body 20, the tunnel film 33 and the charge storage film 32.

Consequently, the channel body 20 has no substantial unevenness that disturbs current flow and extends approximately flatly in the extending direction of the memory hole MH. For this reason, a sufficiently large cell current can be obtained. That is, in the embodiment, unevenness is provided on the memory film 30, thereby preventing the cell current from lowering at the time of reading, while improving the charge holding property.

The above-mentioned plurality of memory strings MS are provided in a memory cell array region on the substrate 10. A peripheral circuit for controlling the memory cell array is provided, for example, in the periphery of the memory cell array region on the substrate 10.

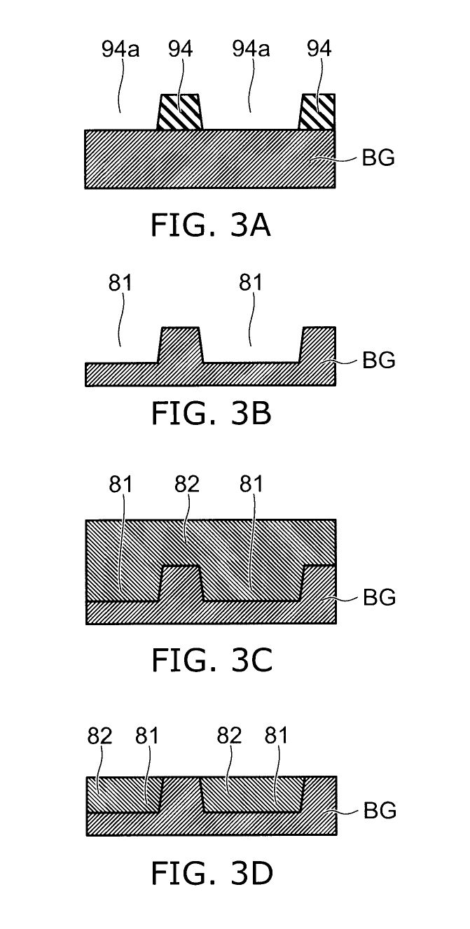

Next, with reference to FIGS. 3A to 6B, a manufacturing method of the semiconductor device 1 of the embodiment will be described. In following description, a forming method of the memory cell array will be described.

The back gate BG is provided on the substrate 10 through an insulating layer not shown. The back gate BG is, for example, a silicon layer doped with an impurity such as boron. As shown in FIG. 3A, a resist 94 is formed on the back gate BG. The resist 94 is patterned and has a selectively formed opening 94a.

Then, through the use of the resist 94 as a mask, the back gate BG is selectively dry-etched. Thereby, as shown in FIG. 3B, a depression part 81 is formed on the back gate BG.

Next, as shown in FIG. 3C, a sacrifice film 82 is buried in the depression part 81. The sacrifice film 82 is, for example, a silicon nitride film, a non-doped silicon film or the like. After that, the whole face of the sacrifice film 82 is etched as shown in FIG. 3D to expose the surface of the back gate BG between the depression part 81 and the depression part 81.

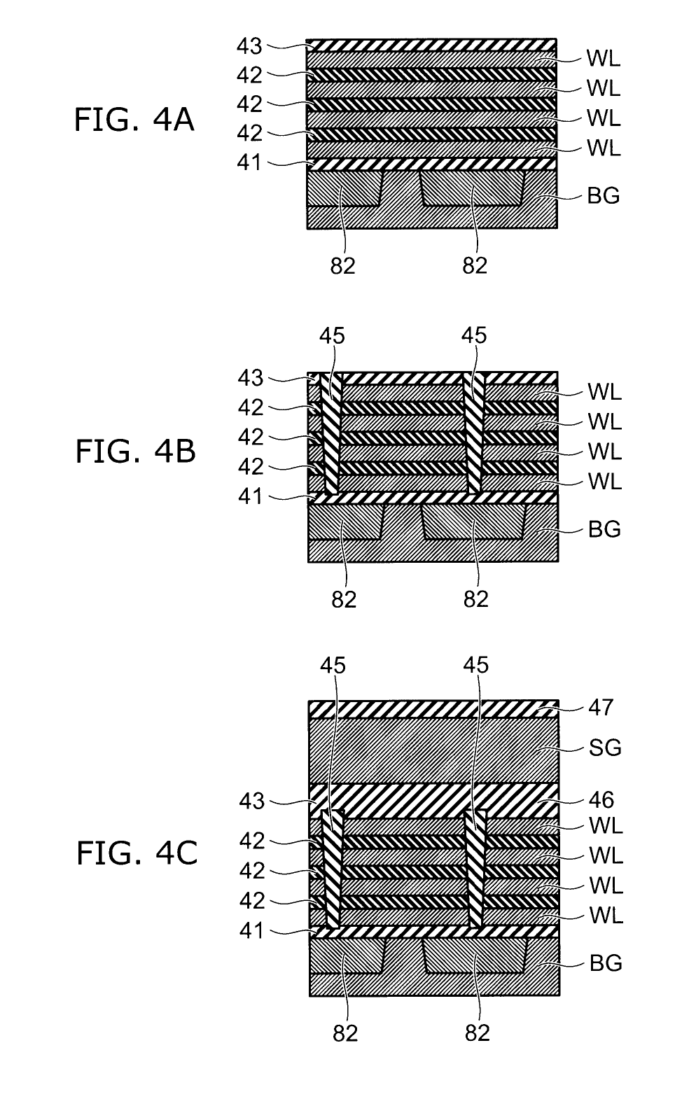

Then, an insulating film 41 is formed on the back gate BG as shown in FIG. 4A, and then, a stacked body including the plurality of electrode layers WL is formed. The insulating layer 42 is formed between the electrode layers WL. An insulating film 43 is formed on the uppermost electrode layer WL.

Subsequently, by photolithography and etching, the stacked body is divided to form a groove reaching the insulating film 41, and then, as shown in FIG. 4B, the groove is filled with an insulating film 45.

After the groove is filled with the insulating film 45, the insulating film 43 is exposed by etching of the whole face. As shown in FIG. 4C, an insulating film 46 is formed on the insulating film 43. Further, the selection gate SG is formed on the insulating film 46 and an insulating film 47 is formed on the selection gate SG.

Next, as shown in FIG. 5A, holes h are formed in the stacked body on the back gate BG. The holes h are formed by using a mask not shown according to, for example, a Reactive Ion Etching (RIE) method. A lower end of each hole h reaches the sacrifice film 82 and the sacrifice film 82 is exposed on the bottom of the hole h. The pair of holes are located on one sacrifice film 82 so as to sandwich the insulating film 45 located substantially at the center of the sacrifice film 82.

Then, the sacrifice film 82 is removed through the holes h, for example, by wet etching. Examples of an etching solution used at this time include an alkaline chemical such as KOH (potassium hydroxide).

Thereby, as shown in FIG. 5B, the sacrifice film 82 is removed. The depression part 81 is formed on the back gate BG by removing the sacrifice film 82. The pair of holes h are connected to each other in one depression part 81. That is, the lower ends of the pair of holes h are connected to one common depression part 81 to form one U-like memory hole MH.

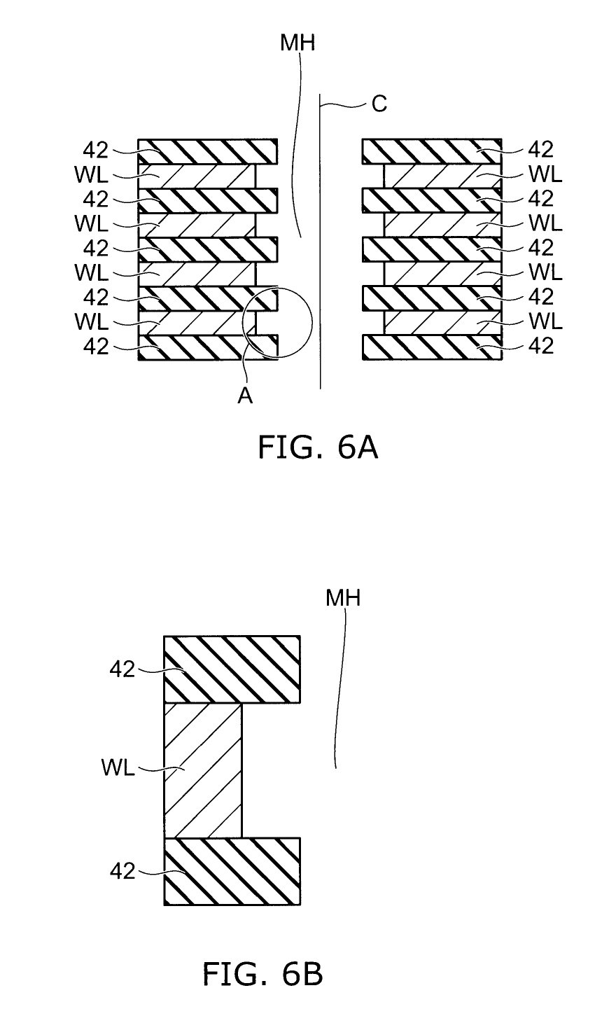

After forming by RIE, processing residues are removed by wet treatment. After that, the electrode layer WL is selectively etched relative to the insulating layer 42. Thereby, as shown in FIG. 6A, the electrode layer WL is retracted further than the insulating layer 42 is retracted in the direction of going away from a center axis C of the memory hole MH, thereby forming a step between the insulating layer 42 and the electrode layer WL. FIG. 6B is an enlarged view of a section A in FIG. 6A.

After that, as shown in FIGS. 2A and 2B, the above-mentioned memory film 30 is formed on an inner wall of the memory hole MH. The gate insulating films 35 and 36 are formed on the side wall of the memory hole MH, on which the selection gate SG is exposed.

Further, a silicon film as the channel body 20 is formed on the inner side of the memory film 30 and the gate insulating film 35 and 36 in the memory hole MH.

Thereafter, a groove is formed on the selection gate SG to be divided into the drain-side selection gate SGD and the source-side selection gate SGS, and after that, a contact electrode not shown, the source layer SL and the bit lines BL in FIG. 1 are formed.

For example, when a film containing a silicon oxide as a main component is formed as the block film 31, the film can be formed according to an Atomic Layer Deposition (ALD) method using Tris(dimethylamino)silane (TDMAS) and O₃ or a Low Pressure Chemical Vapor Deposition (LPCVD) method using dichlorosilane (DSC) and N₂O.

The charge storage film 32 can be formed according to, for example, the LPCVD method using DSC and NH₃ as raw materials or an ALD method of alternately supplying DSC and NH₃ gas.

The tunnel film 33 can be formed according to, for example, the ALD method using TDMAS and O₃.

In order to form the memory film 30 in the shape shown in FIG. 2B, it is preferred that a retraction amount d3 of the electrode layer WL from the insulating layer 42 is set to one third of the thickness of the electrode layer WL and the block film 31 is formed so as to have the same film thickness as d3.

After forming of the memory film 30, amorphous silicon as a protective film is formed on the side wall of the memory hole MH according to the LPCVD method using silane as a raw material under 500 to 600° C., and the memory film 30 on the bottom face of the memory hole MH and the upper face of the stacked body is removed according to RIE.

Then, after cleaning, amorphous silicon as the channel body 20 is formed on the tunnel film 33 according to the LPCVD method using silane as a raw material under 500 to 600° C., and then, is crystallized by annealing to form polycrystalline silicon.

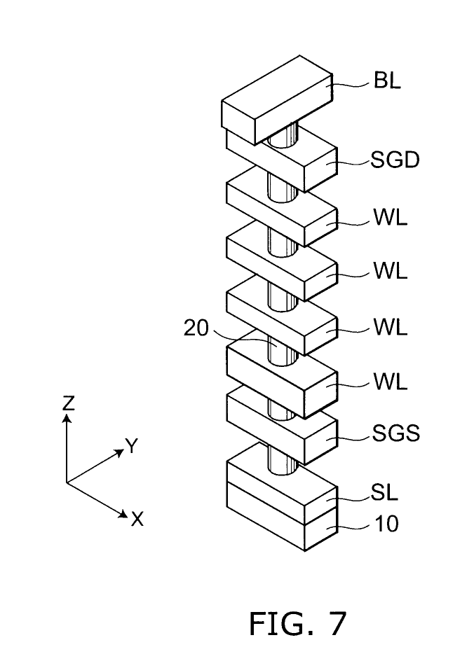

The memory string is not necessarily shaped like U and may be shaped like I as shown in FIG. 7. FIG. 7 shows only conductive parts and insulating parts are not shown.

With this configuration, the source layer SL is provided on the substrate 10, the source-side selection gate (or lower selection gate) SGS is provided on the source layer SL, the plurality of (for example, four) electrode layers WL are provided on the SGS and the drain-side selection gate (or upper selection gate) SGD is provided between the uppermost electrode layer WL and the bit line BL.

Also in the memory string, the memory film 30 shown in FIGS. 2A and 2B is provided between the electrode layers WL and the channel body 20.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device comprising:
a substrate;
a stacked body including a plurality of electrode layers and a plurality of insulating layers which are alternately stacked above the substrate;
a first insulating film provided on a side wall of a hole which is formed through the stacked body and extending in a stacking direction;
a charge storage film provided on an inner side of the first insulating film;
a second insulating film provided on an inner side of the charge storage film; and
a channel body provided on an inner side of the second insulating film,
the charge storage film including a protrusion part which protrudes toward the electrode layer with facing the electrode layer and has a film thickness thicker than a film thickness of a part other than the protrusion part.

2. The device according to claim 1, wherein a distance between the electrode layer and the channel body is longer than a distance between the insulating layer and the channel body.

3. The device according to claim 1, wherein an end of the protrusion part on the side of the electrode layer and a side wall of the protrusion part on the side of the insulating layer are covered with the first insulating film.

4. The device according to claim 1, wherein
a film thickness difference between a part facing the protrusion part of the charge storage film and a part not facing the protrusion part in the second insulating film is smaller than a film thickness difference between the protrusion part and the other part in the charge storage film, and
a film thickness difference between a part facing the protrusion part and a part not facing the protrusion part in the channel body is smaller than the film thickness difference in the second insulating film.

5. The device according to claim 1, wherein a local protruding amount of the channel body toward the electrode layer is smaller than a local protruding amount of the second insulating film toward the electrode layer, and the local protruding amount of the second insulating film toward the electrode layer is smaller than a local protruding amount of the charge storage film toward the electrode layer.

6. The device according to claim 1, wherein the insulating layer protrudes toward the channel body further than the electrode layer protrudes, and a step is formed between the insulating layer and the electrode layer.

7. The device according to claim 6, wherein the first insulating film is provided along the step and a depression part is formed on the first insulating film on a side of the charge storage film.

8. The device according to claim 7, wherein the protrusion part of the charge storage film is provided on the depression part.

9. The device according to claim 1, wherein a film thickness of the first insulating film between the electrode layer and the charge storage film at a center in a thickness direction of the electrode layer is thinner than a film thickness of the first insulating film between the electrode layer and the charge storage film in a vicinity of ends in the thickness direction of the electrode layer.

10. The device according to claim 1, wherein at an intersecting part of the channel body and the electrode layer, the channel body is surrounded by the electrode layer through the first insulating film, the charge storage film and the second insulating film.

11. A semiconductor device comprising:
a substrate;
a stacked body including a plurality of electrode layers and a plurality of insulating layers which are alternately stacked above the substrate;
a first insulating film provided on a side wall of a hole which is formed through the stacked body and extending in a stacking direction;
a charge storage film provided on an inner side of the first insulating film;
a second insulating film provided on an inner side of the charge storage film; and
a channel body provided on an inner side of the second insulating film,
a distance between the electrode layer and the channel body being longer than a distance between the insulating layer and the channel body.

12. The device according to claim 11, wherein a local protruding amount of the channel body toward the electrode layer is smaller than a local protruding amount of the second insulating film toward the electrode layer, and the local protruding amount of the second insulating film toward the electrode layer is smaller than a local protruding amount of the charge storage film toward the electrode layer.

13. The device according to claim 11, wherein the insulating layer protrudes toward the channel body further than the electrode layer protrudes, and a step is formed between the insulating layer and the electrode layer.

14. The device according to claim 13, wherein the first insulating film is provided along the step and a depression part is formed on the first insulating film on a side of the charge storage film.

15. The device according to claim 11, wherein a film thickness of the first insulating film between the electrode layer and the charge storage film at a center in a thickness direction of the electrode layer is thinner than a film thickness of the first insulating film between the electrode layer and the charge storage film in a vicinity of ends in the thickness direction of the electrode layer.

16. The device according to claim 11, wherein at an intersecting part of the channel body and the electrode layer, the channel body is surrounded by the electrode layer through the first insulating film, the charge storage film and the second insulating film.
